(19) United States
(12) Patent Application Publication
(10) Pub. No.: US 2014/0174493 A1
(43) Pub. Date: Jun. 26, 2014

(54) NANOCOMPOSITE THERMOELECTRIC CONVERSION MATERIAL AND METHOD OF MANUFACTURE THEREOF

(71) Applicants: Junya Murai, Susono-shi (JP); Takuji Kita, Numazu-shi (JP)

(72) Inventors: Junya Murai, Susono-shi (JP); Takuji Kita, Numazu-shi (JP)

(73) Assignee: TOYOTA JIDOSHA KABUSHIKI KAISHA, Toyota-shi, Aichi-ken (JP)

(21) Appl. No.: 14/237,443

(22) PCT Filed: Aug. 9, 2012
(86) PCT No.: PCT/IB2012/001533

§ 371 Date: Feb. 6, 2014

(30) Foreign Application Priority Data
Aug. 12, 2011 (JP) 2011-176748

(51) Int. Cl. H01L 35/16

(52) U.S. Cl. CPC H01L 35/16
USPC 136/200; 264/5

(57) ABSTRACT

A nanocomposite thermoelectric conversion material includes a matrix and semiconductor nanowires dispersed as a dispersant in the matrix. The semiconductor nanowires are arranged unidirectionally in a long axis direction of the semiconductor nanowires.

### BACKGROUND OF THE INVENTION

1. Field of the Invention

The invention relates to a nanocomposite thermoelectric conversion material and a method of manufacturing the same.

2. Description of the Related Art

Thermoelectric conversion materials are capable of converting heat energy into electric energy and vice versa. Thermoelectric materials make up thermoelectric conversion elements which are used as thermoelectric cooling elements and thermoelectric heating elements. Such thermoelectric conversion materials perform thermoelectric conversion by utilizing the Seebeck effect. The thermoelectric conversion performance is expressed by formula (1) below, which is referred to as the “performance index ZT”:

ZT=α²σT/κ

(wherein α is the Seebeck coefficient, σ is the electrical conductivity, κ is the thermal conductivity, and T is the measurement temperature).

As is apparent from formula (1) above, to increase the thermoelectric conversion performance of a thermoelectric conversion material, the Seebeck coefficient α and the electric conductivity σ of the material used for the thermoelectric conversion material should be made larger, and the thermal conductivity κ should be made smaller. In order to lower the thermal conductivity κ of such a material, it has been proposed that the thermoelectric conversion material is formed into a composite by adding, to particles of a starting material for a thermoelectric conversion material, fine particles of an insulating material such as a ceramic which does not react with the matrix of the thermoelectric conversion material (i.e., inert fine particles) (see, for example, Japanese Patent Application Publication No. 2010-114419 (JP-2010-114419A)).

In JP-2010-114419 A, heat scatters at the inert fine particle interfaces; hence, the thermal conductivity κ abruptly falls, making it possible to increase the performance index ZT. However, because the ceramic that is added into the thermoelectric conversion material is an insulating material, the electrical conductivity ends up decreasing. Moreover, given that insulating materials lack electrical properties, there is no rise in the Seebeck coefficient. Therefore, in terms of the parameters other than the thermal conductivity, the increase in the performance index ZT is not sufficient.

### SUMMARY OF THE INVENTION

The invention provides a thermoelectric conversion material having an excellent performance index, and a method of manufacturing such a material.

The nanocomposite thermoelectric conversion material according to a first aspect of the invention includes a matrix, and semiconductor nanowires dispersed as a dispersant in the matrix. The semiconductor nanowires are arranged unidirectionally in the long axis direction of the semiconductor nanowires.

In this first aspect of the invention, semiconductor nanowires are dispersed as a dispersant in the thermoelectric conversion material matrix, thereby lowering the thermal conductivity. In addition, because the semiconductor nanowires are arranged unidirectionally in the long axis direction thereof, the Seebeck coefficient rises, markedly enhancing the performance index ZT.

The nanocomposite thermoelectric conversion material manufacturing method according to a second aspect of the invention includes preparing a fluid that contains salts each of which has a different element making up a thermoelectric conversion material, which the salts being formed into a matrix and a dispersant that have same slip plane; producing composite particles of the thermoelectric conversion material by adding, in a dropwise manner, a solution containing a reducing agent to the fluid; and applying pressure to the composite particles such that the dispersant is formed into nanowires and the nanowires are arranged unidirectionally. The dispersant fluid includes a solution or a slurry.

### BRIEF DESCRIPTION OF THE DRAWINGS

Features, advantages, and the technical and industrial significance of exemplary embodiment of the invention will be described below with reference to the accompanying drawings, in which like numerals denote like elements, and wherein:

FIG. 1 is a schematic diagram of a nanocomposite thermoelectric conversion material according to an embodiment of the invention;

FIGS. 2A to 2C are schematic diagrams showing nanocomposite thermoelectric conversion material manufacturing steps according to an embodiment of the invention;

FIGS. 3A to 3C are schematic diagrams showing nanocomposite thermoelectric conversion material manufacturing steps in Examples 1 and 2 of the invention.;

FIG. 4 is a flow chart of the nanocomposite thermoelectric conversion material production steps in Examples 1 and 2 of the invention;

FIG. 5 is an x-ray diffraction (XRD) chart of the nanocomposite thermoelectric conversion material obtained in Example 1;

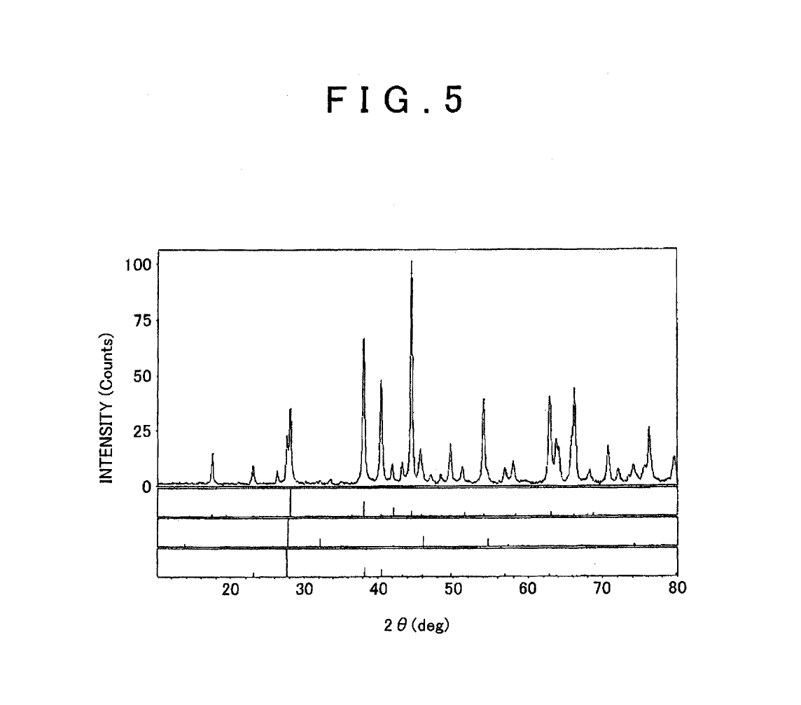

FIG. 6 is a transmission electron microscopy (TEM) image of the nanocomposite thermoelectric conversion material obtained in Example 1;

FIG. 7 is a flow chart of the nanocomposite thermoelectric conversion material production steps in Examples 3 and 4 of the invention;

FIG. 8 is an XRD chart of the nanocomposite thermoelectric conversion material obtained in Example 3; and

FIG. 9 is a TEM image of the nanocomposite thermoelectric conversion material obtained in Example 3.

### DETAILED DESCRIPTION OF EMBODIMENTS

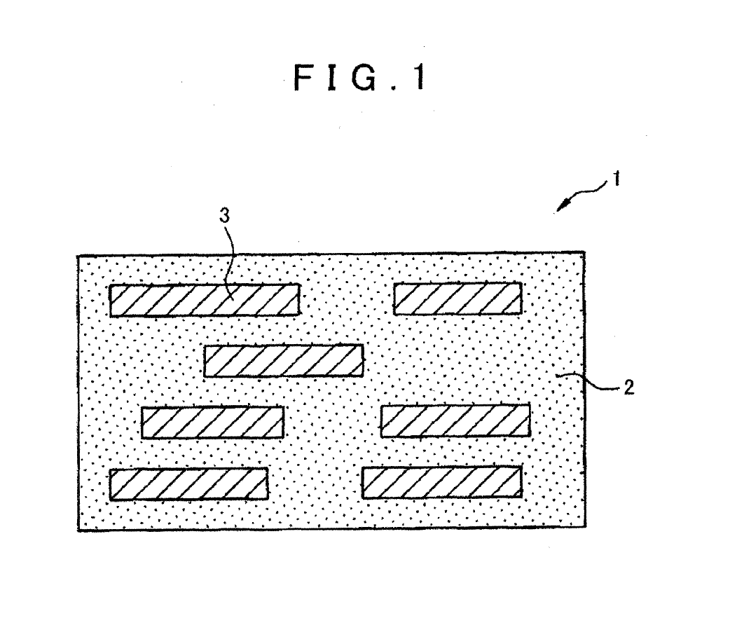

FIG. 1 is a schematic diagram of a nanocomposite thermoelectric conversion material 1 according to an embodiment of the invention. As shown schematically in FIG. 1, a nanocomposite thermoelectric conversion material 1 includes semiconductor nanowires 3 dispersed as a dispersant in a matrix 2. The semiconductor nanowires 3 are arranged unidirectionally in a long axis direction thereof.

The thermoelectric conversion material making up the matrix 2 may be a p-type material or an n-type material. The p-type thermoelectric conversion materials are not limited to particular materials. For example, Bi₂Te₃ alloys, PbTe alloys, Zn₄Sb₃ alloys, CoSb₃ alloys, half-Heusler alloys, full-Heusler alloys, and SiGe alloys may be used as the p-type thermoelectric conversion materials. Likewise, n-type thermoelectric conversion materials are not limited to particular materials. For example, known materials such as Bi₂Te₃ alloys, PbTe alloys, Zn₄Sb₃ alloys, CoSb₃ alloys, half-Heusler alloys, full-Heusler alloys, SiGe alloys, Mg₂Si alloys, Mg₂Sn alloys, and CoSi alloys may be used as the n-type thermoelectric conversion materials. Among the above materials, a material selected from among (Bi,Sb)₂(Te,Se)₃ alloys, CoSb₃ alloys, PbTe alloys, and SiGe alloys may be preferably used as the n-type thermoelectric conversion materials. (Bi,Sb)₂(Te,Se)₃ alloys, CoSb₃ alloys, PbTe alloys, and SiGe alloys are thermoelectric conversion materials commonly considered to be of high performance.

The semiconductor nanowires dispersed as a dispersant in this matrix are a very small, nanometer-size, wire-like material. The semiconductor nanowires have a length in the long axis direction which is longer than the width in a cross-section orthogonal to the long axis direction. The length in the long axis direction of these nanowires is preferably at least 10 nm, and more preferably at least 50 nm. The width of the nanowires is preferably at most 20 nm, and more preferably at most 10 nm. This length refers to the length as measured by TEM.

In order to exhibit the intended effects, these nanowires have a volume fraction within the nanocomposite thermoelectric conversion material of preferably from 5 to 50 vol %, and more preferably from 20 to 50 vol %.

A semiconductor material which has no reactivity with the material making up the matrix is used as the nanowire material. Specifically, use may be made of any material which has a predetermined proportion thereof at which the semiconductor material does not enter into solid solution in the respective matrixes on a phase diagram, and which moreover has semiconductor properties. For example, the predetermined proportion includes a proportion of an atomic radius of the matrix to an atomic radius of the semiconductor material. The material making up the nanowires preferably has a higher Seebeck coefficient than one the material making up the matrix has. By using a material having a higher Seebeck coefficient than the matrix, the degree of increase in the Seebeck coefficient of the resulting nanocomposite thermoelectric conversion material becomes larger. In addition, it is preferable to use the material making up the matrix and the material making up the nanowires in combinations such that the respective materials have similar temperature dependencies relating to a thermoelectric property. Exemplary matrix/nanowire combinations include (Bi,Sb)₂(Te,Se)₃/Te, (Bi,Sb)₂(Te,Se)₃/Bi, Bi₂Te₃/Sb₂Te₃, SiGe/Si, SiGe/Ge, (TiNiSn/Sn), and Mg₂Si/Si.

The nanowires are preferably arranged at a spacing of at most 20 nm in a direction orthogonal to the nanowire long axis direction. By adopting such a spacing, the nanowires acquire a stacked structure. In this way, units having a very high density of state, i.e., a very high Seebeck coefficient, are formed. When such units are arranged and formed into a composite, the Seebeck coefficient also considerably increases.

In conventional methods, the nanowires are manufactured by casting a semiconductor material melt onto an aluminum template containing holes of nanoscale diameter, then dissolving the aluminum template with an alkali solution of, for example, sodium hydroxide. The resulting nanowires are added, using a ball mill, or the like, to the material making up the matrix, thereby forming a composite. Subsequently, the composite is press-sintered to produce a nanocomposite thermoelectric conversion material.

However, when nanowires are produced, then incorporated into the matrix as noted above, all of the nanowires do not acquire a unidirectional arrangement. That is, the proportion of unidirectionally arranged nanowires is low.

Hence, in the working examples of the invention, first, a solution containing a reducing agent is added dropwise to a solution or slurry containing salts each of which has a different element making up thermoelectric conversion materials. In this way, the ions making up the salts are reduced and the corresponding atoms deposit out, resulting in the formation of composite particles. The composite particles are composed of a plurality of different thermoelectric conversion materials that are nanometer-scale particles. Here, it is preferable to use a combination of materials having the same slip plane in the matrix and the dispersant, which the matrix and the dispersant are included in the thermoelectric conversion materials. “Saks of the elements making up thermoelectric conversion materials” signifies, for example, in a case where the thermoelectric conversion material is CoSb₃: cobalt chloride hydrate and antimony chloride; and in a case where the thermoelectric conversion material is Co_{0.94}Ni_{0.06}Sb₃: cobalt chloride hydrate, nickel chloride, and antimony chloride. No particular limitation is imposed on the content of the salts of elements making up this thermoelectric conversion material in the solution or slurry. That is, it is preferable to suitably adjust the content according to the types of solvents and starting materials used. The combination of matrix and dispersant may be the above-described matrix/nanowire combination, such as (Bi,Sb)₂Te₃ and Te. Solvent which dissolves or disperses salts of the elements making the thermoelectric conversion material may be available. For example, the solvent may be an alcohol, water, or the like. Preferably, the solvent may be an ethanol. The reducing agent may be one which is capable of reducing ions of the elements making up the thermoelectric conversion material. For example, NaBH₄, hydrazide, or the like may be used for this purpose.

When a reducing agent is added to a solution containing salts of the elements making up the thermoelectric conversion material, ions of the elements making up the thermoelectric conversion material are reduced, and these elements deposit out. In the course of such reduction, in addition to the Bi particles and Te particles which make up the thermoelectric conversion material, by-products such as NaCl and NaBO₃ also form. It is desirable to carry out filtration in order to remove these by-products. Also, following filtration, it is desirable to add an alcohol or water and thereby wash away the by-products.

The resulting dispersion of composite particles of the thermoelectric conversion material is heat-treated, preferably by hydrothermal treatment, then dried, giving an agglomerate. The resulting agglomerate is rinsed and dried as needed, then subjected to a common sintering process, such as spark plasma sintering (SAS). In this way, nanoparticles of the semiconductor material disperse in the matrix of the thermoelectric conversion material, giving composite particles which make up the dispersed phase.

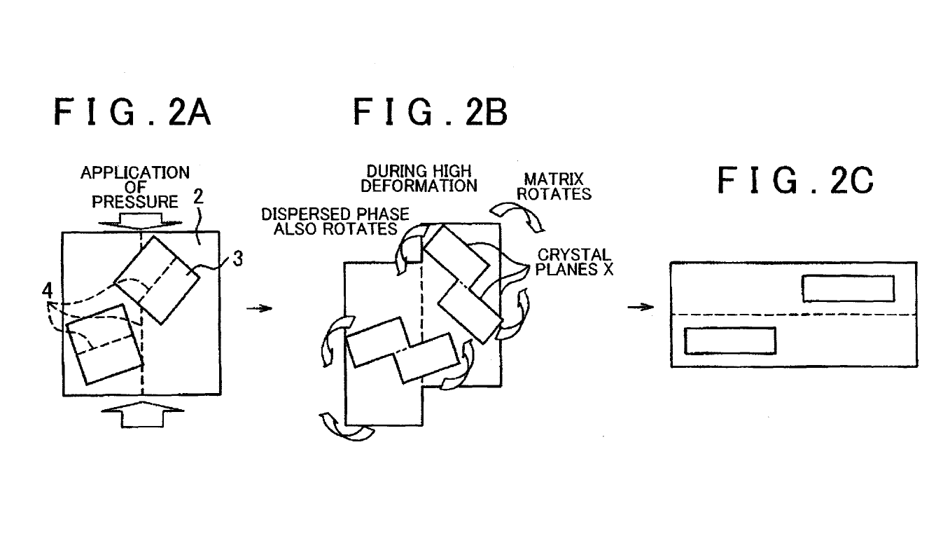

The composite material thus obtained is subjected to the application of pressure by high deformation, as shown in FIGS. 2A to 2C. Because the matrix 2 and the dispersant 3 are materials having the same slip planes 4, such application of pressure gives rise to crystal slipping at the slip planes (FIG. 2A). As a result, the matrix rotates and the dispersant also rotates (FIG. 2B), bringing the crystal planes X into an arrangement that is perpendicular to the plane in which pressure is applied. Moreover, due to crystal growth, the dispersant forms into wires, which are arranged unidirectionally (FIG. 2C).

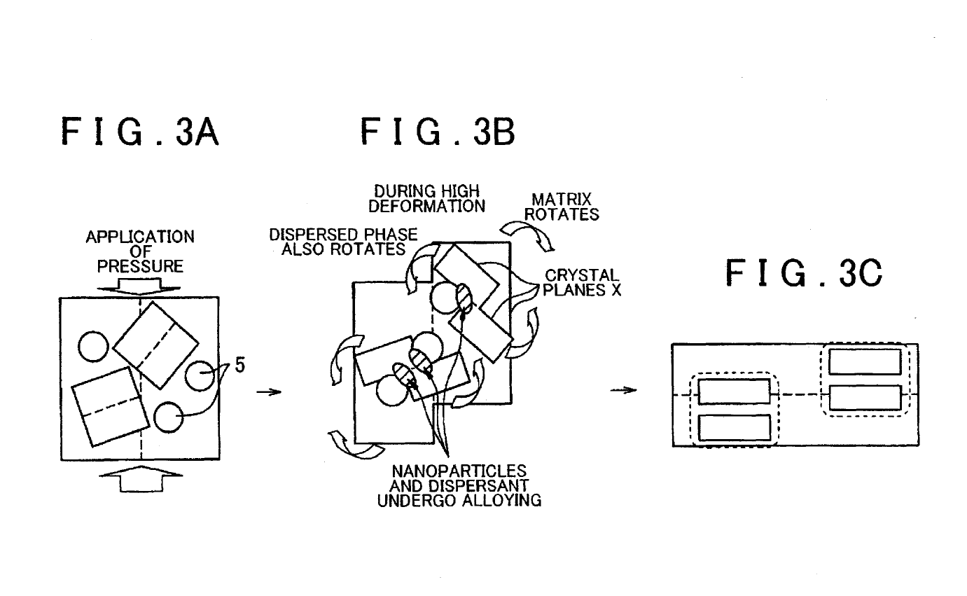

At the time of such high deformation, as shown in FIGS. 3A to 3C, it is preferable to add, into the composite material, nanoparticles 5 of an element which is a constituent element of the matrix and is reactive with the dispersant. In cases where (Bi,Sb)₂Te₃ is used as the matrix and tellurium is used as the dispersant, tellurium may be used as this element. Here, the tellurium that serves as the nanoparticles 5 refers to an unreacted elemental substance.

In this case, as in the case shown in FIGS. 2A to 2C, due to the application of pressure, high deformation gives rise crystal sliding in the slip plane (FIG. 3A). When this happens, the matrix rotates and the dispersant also rotates (FIG. 3B), bringing the crystal planes X into an arrangement that is perpendicular to the plane in which pressure is applied. Moreover, due to crystal growth, the dispersant forms into wires, which are arranged unidirectionally (FIG. 3C). In the course of such rotation, alloying reactions between the nanoparticles 5 and the dispersant simultaneously proceed (FIG. 3B). As a result, a matrix forms in which the spacing between the nanowires has been controlled to a size that is similar to the width of the nanowires, and a unit of stacked nanowires forms. Here, “a size that is similar” signifies a nanometer-scale size.

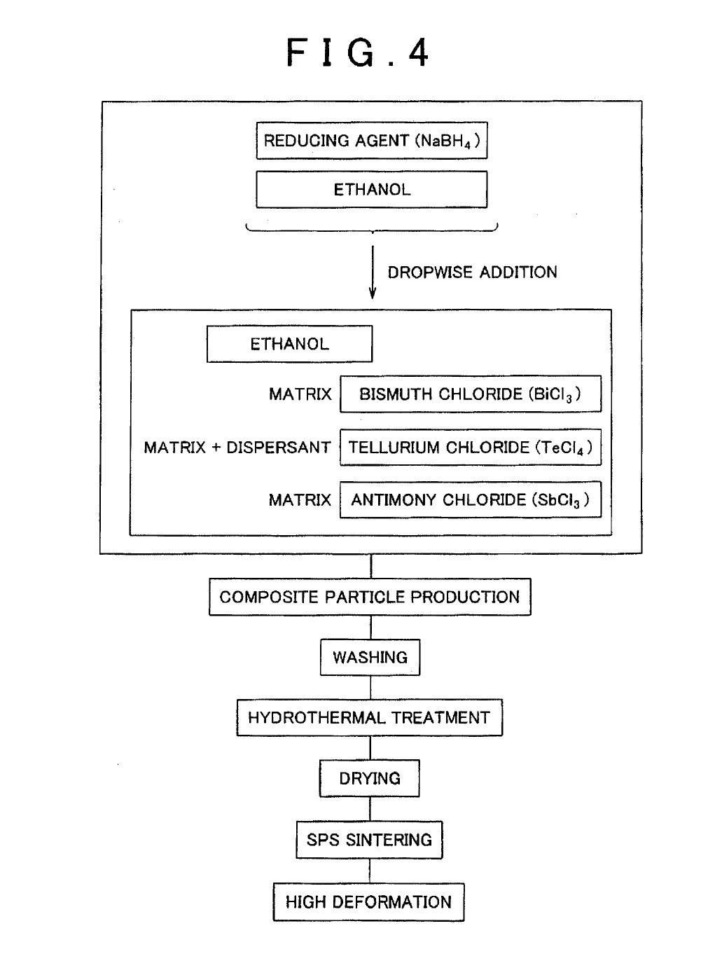

The nanoparticles of Examples 1 and 2 were synthesized by the production process in the flow chart shown in FIG. 4. The amounts of the respective ingredients, in order starting with the ingredients at the top of the flow chart, were as follows: reducing agent (NaBH₄), 2.4 g; ethanol, 100 mL; ethanol, 100 mL; bismuth chloride (BiCl₃), 0.4 g; tellurium chloride (TeCl₄), 3.2 g (Example 1), and 3.3 g (Example 2); and antimony chloride (SbCl₃), 1.1 g. Of the various elements, tellurium was charged in a surplus amount relative to the solid solubility limit.

An ethanol slurry containing the nanoparticles thus produced was filtered and washed with 1 liter of water, then filtered and washed with 300 mL of ethanol.

The filtered and washed material was then placed in a closed autoclave. The filtered and washed material was alloyed after carrying out 48 hours of hydrothermal treatment at 240° C. This resulted in the deposition of surplus tellurium as nanoparticles and the formation of composite nanoparticles composed of (Bi,Sb)₂Te₃ as the matrix and tellurium as the dispersed phase. The matrix and dispersed phase were both hexagonal systems, and had the same slip planes.

Next, the composite nanoparticles were dried in a stream of nitrogen, and 2.1 g of a powder was recovered.

The powder obtained was subjected to SPS at 360° C., yielding a bulk body of nanocomposite thermoelectric conversion material.

High deformation was subsequently applied under the conditions shown in the following table.

TABLE 1

| | |
|---|---|
| Working ratio (%) | 50 |
| Pressure (MPa) | 40 |
| Working temperature (° C.) | 350 |
| Temperature increasing rate (° C./min) | 10 |
| Cooling rate (° C./min) | 5 |
| Holding time (min) | 15 |

During such high deformation, the tellurium slipped in the slip plane, rotated and formed into nanowires, which nanowires then grew and acquired an arrangement within the electrically conductive plane of the matrix during cooling.

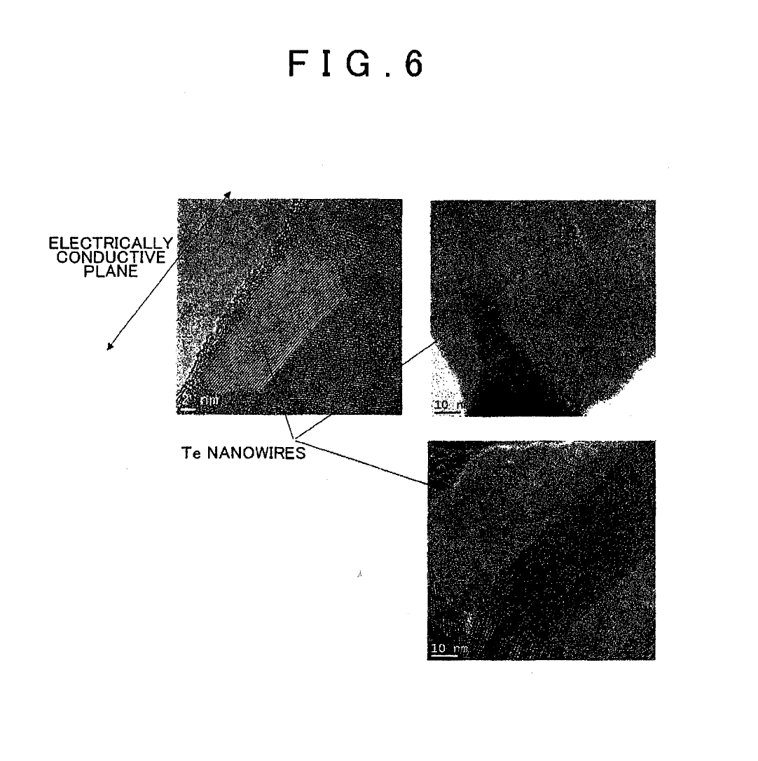

XRD analysis and TEM observation were carried out on the resulting powder. FIG. S shows an XRD chart, and FIG. 6 shows a TEM image. As shown in the XRD chart, diffraction peaks for (Bi,Sb)₂Te₃ and diffraction peaks for tellurium were distinctly observed. Thus, it was confirmed that the powder was composed of the matrix which included Te₃ and the dispersed phase which included tellurium. Moreover, it was confirmed from the TEM image that the tellurium nanowires were arranged unidirectionally in the long axis direction thereof and parallel to the electrically conductive plane of the matrix.

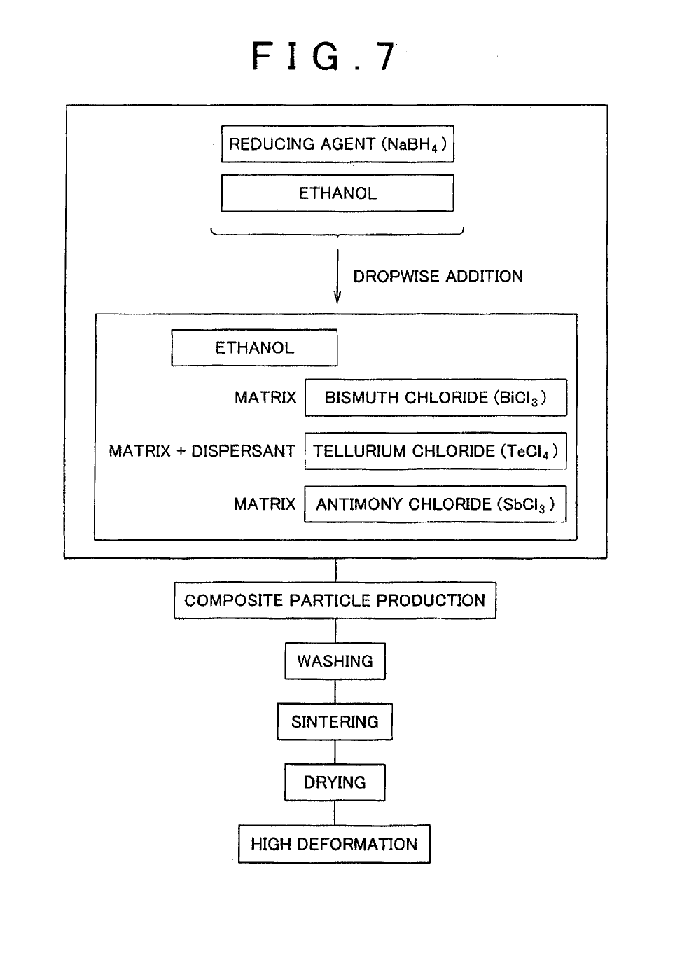

The nanoparticles of Examples 3 and 4 were synthesized by the production process in the flow chart shown in FIG. 7. The amounts of the respective ingredients, in order starting with the ingredients at the top of the flow chart, were as follows: reducing agent (NaBH₄), 2.4 g; ethanol, 100 mL; ethanol, 100 mL; bismuth chloride (BiCl₃), 0.4 g; tellurium chloride (TeCl₄), 3.3 g (Example 3) and 2.8 g (Example 4); and antimony chloride (SbCl₃), 1.1 g. Of the various elements, tellurium was charged in a surplus amount relative to the solid solubility limit.

An ethanol slurry containing the nanoparticles thus produced was filtered and washed with a solution composed of 500 mL of water and 300 mL of ethanol, then filtered and washed with 300 mL of ethanol.

The filtered and washed material was then hot press (HP) sintered at 300° C. for 7 hours. At this time, because alloying has not yet proceeded to completion, the elements bismuth and antimony making up the matrix are present in the vicinity of the tellurium nanoparticles.

Next, the sintered material was dried in a stream of nitrogen, and 2.0 g of a powder was obtained.

The powder obtained was subjected to high deformation under the conditions shown in the following table. Here, the powder was gradually cooled at a very slow cooling rate of 1.5° C./min.

TABLE 2

| | |
|---|---|
| Change in thickness (%) | 50 |
| Pressure (MPa) | 40 |
| Working temperature (° C.) | 350 |
| Temperature increasing rate (° C./min) | 10 |
| Cooling rate (° C./min) | 1.5 |
| Holding time (min) | 15 |

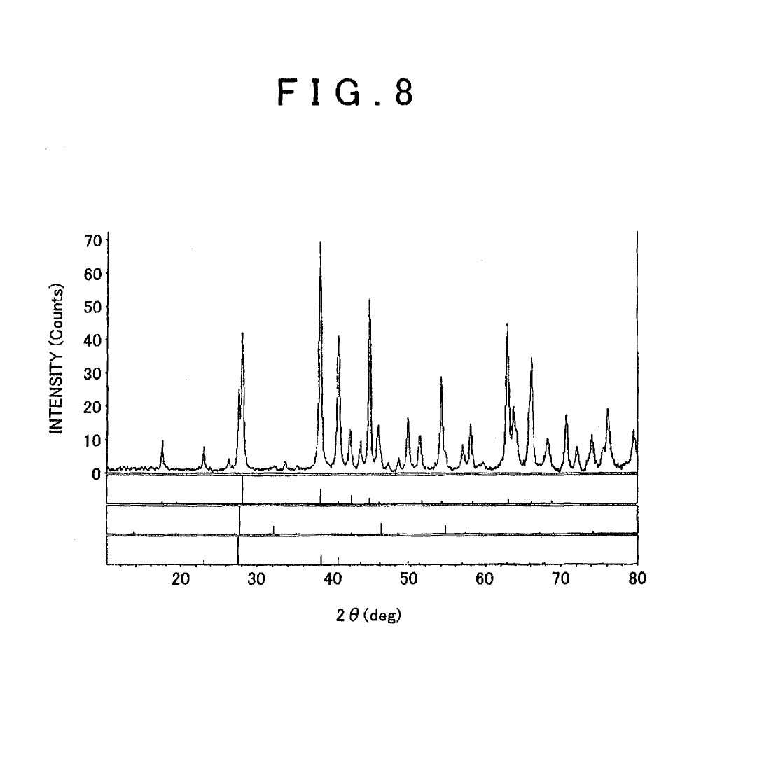

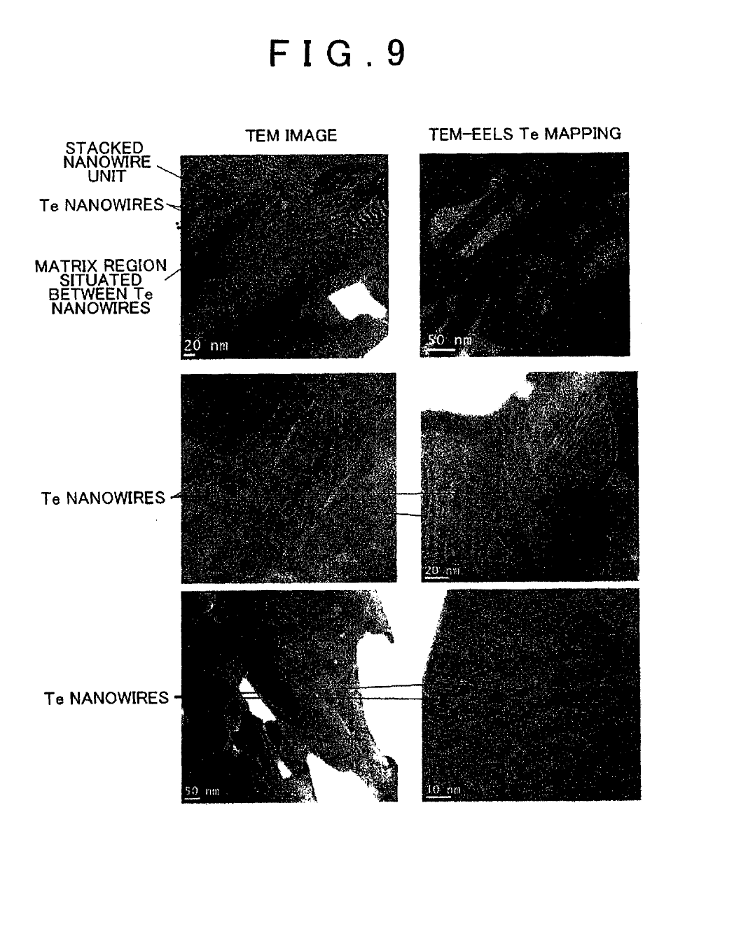

XRD analysis and TEM observation were carried out on the resulting powder. FIG. 8 shows an XRD chart, and FIG. 9 shows a TEM image. As shown in the XRD chart, diffraction peaks for (Bi,Sb)₂Te₃ and diffraction peaks for tellurium were distinctly observed. Thus, it was confirmed that the powder was composed of the matrix which included Te₃ and the dispersed phase which included tellurium. Moreover, from the TEM image, the tellurium nanowires were confirmed to be arranged unidirectionally in the long axis direction thereof and parallel to the electrically conductive plane of the matrix.

The Seebeck coefficient, specific electrical resistance, thermal conductivity, and performance index ZT at room temperature were measured as performance values for the nanocomposite thermoelectric-conversion materials thus produced. The results are shown in the table below. Here, the thermal conductivity was measured by a stationary thermal conductivity evaluation method, and by a flash method (non-stationary method) using a thermal conductivity measuring flash apparatus (manufactured by Netzsch). The Seebeck coefficient was measured with a ZEM system (manufactured by Ulvac-Riko, Inc.) by 3-point fitting of ΔV/ΔT. The specific electrical resistance was measured by the 4-probe method using the ZEM system manufactured by Ulvac-Riko, Inc.

TABLE 3

| | | specific | Thermal | | | |
|---|---|---|---|---|---|---|
| | Seebeck | electrical | conduc- | | Te | |
| | coefficient | resistance | tivity | | content | Sb₂O₃ |
| | (μV · K) | (μΩm) | (W/m · K) | ZT | (vol %) | content |
| Example 1 | 226 | 21 | 0.50 | 1.5 | 20 | — |
| Example 2 | 238 | 22 | 0.43 | 1.8 | 25 | — |
| Example 3 | 258 | 25 | 0.44 | 1.9 | 25 | — |
| Example 4 | 245 | 24 | 0.50 | 1.5 | 10 | — |
| Comparative | 202 | 25 | 0.49 | 1.0 | 0 | 5.0 |
| example | | | | | | |

In this table, the nanoparticles in the comparative example were manufactured by the same process as in Example 1, but without charging tellurium and without carrying out either pre-annealing or orientation treatment. However, a surplus of antimony was charged into the nanoparticles of the comparative example and oxidized, thereby dispersing Sb₂O₃ (an insulator). Because these nanoparticles included an insulator as the dispersant, the lattice thermal conductivity decreased markedly, as a result of which the ZT improved. In the nanocomposite thermoelectric conversion materials of the examples of this invention, the Seebeck coefficient also increased considerably.

The lattice thermal conductivity is computed by subtracting the carrier thermal conductivity from the overall thermal conductivity. The carrier thermal conductivity is computed from the following formula.

Kel=LδT

(wherein Kel is the carrier thermal conductivity, L is the Lorentz number, δ is the electrical conductivity (reciprocal of specific electrical resistance), and T is the absolute temperature).

From the above results, nanocomposite thermoelectric materials containing tellurium (a semiconductor) nanowires as a dispersant have an improved Seebeck coefficient compared with conventional materials. This appears to be due to the forming, into a composite, tellurium nanowires having an increased density of state and an increased Seebeck coefficient.

1. A nanocomposite thermoelectric conversion material comprising:
a matrix; and
semiconductor nanowires dispersed in the matrix, wherein the semiconductor nanowires are arranged unidirectionally in a long axis direction of the semiconductor nanowires, and
the nanowires have a length of at least 50 nm in the long axis direction and a width of at most 20 nm in a cross-section orthogonal to the long axis direction.

2. (canceled)

3. The nanocomposite thermoelectric conversion material according to claim 1, wherein the nanowires have a volume fraction of from 5 to 50 vol %.

4. The nanocomposite thermoelectric conversion material according to claim 1, wherein the nanowires are arranged at a spacing of at most 20 nm in a direction orthogonal to the long axis direction.

5. The nanocomposite thermoelectric conversion material according to claim 1, wherein the nanowires are arranged parallel to an electrically conductive plane of the matrix.

6. A method of manufacturing a nanocomposite thermoelectric conversion material, comprising:
preparing a fluid that contains salts each of which has a different element making up a thermoelectric conversion material, which the salts being formed into a matrix and a dispersant that have same slip plane;
producing composite particles of the thermoelectric conversion material by adding, in a dropwise manner, a solution containing a reducing agent to the fluid; and
applying pressure to the composite particles such that the dispersant is formed into nanowires and the nanowires are arranged unidirectionally, wherein the fluid includes a solution or a slurry.

7. The manufacturing method according to claim 6, wherein the pressure is applied to the composite particles such that the nanowires are arranged parallel to an electrically conductive plane of the matrix.

8. The manufacturing method according to claim 7, further comprising adding, into the composite particles, nanoparticles of an element which is a constituent element of the matrix and is reactive with the dispersant.
